(19) United States
(12) Patent Application Publication
(10) Pub. No.: US 2026/0068614 A1
(43) Pub. Date: Mar. 5, 2026

(54) SELF ALIGN SPACER CUT PROCESS

(71) Applicant: International Business Machines Corporation, Armonk, NY (US)

(72) Inventors: Xiaoming Yang, Clifton Park, NY (US); Genevieve Beique, Latham, NY (US); Lawrence Alfred Clevenger, Saratoga Springs, NY (US)

(21) Appl. No.: 18/818,098

(22) Filed: Aug. 28, 2024

(51) Int. Cl. H01L 21/033; H01L 21/768

(52) U.S. Cl. CPC H10P 76/4085; H10W 20/081; H10W 20/056; H10W 20/062

(57) ABSTRACT

Methods of forming metal traces and a semiconductor structure are presented. The semiconductor structure comprises a substrate, a cutting pattern formed of hard masks protruding from the substrate, and photoresist positioned over the substrate such that openings in the photoresist direct print trenches to be formed in dielectrics of the substrate and the cutting pattern blocks portions of the openings to form tip-to-tip cuts in the trenches.

### BACKGROUND

The disclosure relates generally to the electrical, electronic, and computer arts, and more specifically, to fabricating semiconductor devices.

Conventionally, metal traces in the interconnect layers of modem semiconductor devices are formed by a process known as self-aligned double patterning (SADP). SADP uses iterative deposition techniques to overcome the known problem that modem feature sizes are too small to be accurately formed using photolithographic techniques alone. That is, current process nodes have sub-wavelength features that are smaller than the extreme ultraviolet (EUV) wavelength that is used for photolithography. SADP uses sacrificial spacers to reduce the feature size to approximately half of the minimum size that can be achieved using EUV photolithography.

However, with self-aligned double patterning (SADP) or direct lithography, although feature sizes may be achieved, other inconsistencies can result. For example, when forming metal traces using direct print, cut line end pull back can result. Additionally, tip-to-tip (T2T) specifications, the distance between metal line ends, are shrinking in modern designs. The conventional lithographic process T2T is usually >25nm, even with EUV.

### SUMMARY

The illustrative examples present methods of using spacers for a self-align spacer cut process. According to an illustrative embodiment, a method of forming metal traces is presented. A preliminary structure is obtained that comprises a substrate, a mandrel protruding from a substrate, and a spacer surrounding the mandrel. The mandrel is pulled from the preliminary structure to leave the spacer on the substrate. A pattern of the spacer is etched into hard masks of the substrate to form a cutting pattern in the hard masks after pulling the mandrel. Trench lithography is performed over the cutting pattern and the substrate. The method etches through dielectrics of the substrate to form trenches while the cutting pattern locally blocks etching to form tip-to-tip cuts between the trenches.

According to another illustrative embodiment, a method of forming metal traces is presented. A preliminary structure is obtained that comprises a substrate, a mandrel protruding from a substrate, and a spacer surrounding the mandrel. The mandrel is pulled to leave the spacer on the substrate. A pattern of the spacer is etched into hard masks of the substrate to form a cutting pattern in the hard masks. Lithography is performed over the cutting pattern and the substrate. Etching through dielectrics of the substrate is performed to form trenches such that the cutting pattern locally blocks etching to form tip-to-tip cuts in the range of 5-10nm between the trenches. The trenches are metallized to form metal traces. Chemical mechanical planarization is performed to remove excess metal.

According to yet another illustrative embodiment, a semiconductor structure is presented. The semiconductor structure comprises a substrate, a cutting pattern formed of hard masks protruding from the substrate, and photoresist positioned over the substrate such that openings in the photoresist direct print trenches to be formed in dielectrics of the substrate and the cutting pattern blocks portions of the openings to form tip-to-tip cuts in the trenches.

In view of the foregoing, techniques of the present invention can provide substantial beneficial technical effects. For example, one or more illustrative examples provide self-aligned spacer cut for forming tip-to-tip cuts between metal traces. The tip-to-tip cuts can be in the range of 5-10nm.

Some embodiments may not have these potential advantages, and these potential advantages are not necessarily required of all embodiments. These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 is a flowchart illustrating steps of a self-aligned patterning process to form metal traces in accordance with an illustrative embodiment;

FIG. 2 is an illustration of a cross-sectional view of a structure produced by depositing precursor films in accordance with an illustrative embodiment;

FIG. 3 is an illustration of a top view of a structure produced by depositing precursor films in accordance with an illustrative embodiment;

FIG. 4 is an illustration of a cross-sectional view of a structure during lithography in accordance with an illustrative embodiment;

FIG. 5 is an illustration of a top view of a structure during lithography in accordance with an illustrative embodiment;

FIG. 6 is an illustration of a cross-sectional view of a structure after mandrel etch in accordance with an illustrative embodiment;

FIG. 7 is an illustration of a top view of a structure after mandrel etch in accordance with an illustrative embodiment;

FIG. 8 is an illustration of a cross-sectional view of a structure after depositing a spacer material in accordance with an illustrative embodiment;

FIG. 9 is an illustration of a top view of a structure after depositing a spacer material in accordance with an illustrative embodiment;

FIG. 10 is an illustration of a cross-sectional view of a structure after performing a spacer etch back in accordance with an illustrative embodiment;

FIG. 11 is an illustration of a top view of a structure after performing a spacer etch back in accordance with an illustrative embodiment;

FIG. 12 is an illustration of a cross-sectional view of a structure after performing a mandrel pull in accordance with an illustrative embodiment;

FIG. 13 is an illustration of a top view of a structure after performing a mandrel pull in accordance with an illustrative embodiment;

FIG. 14 is an illustration of a cross-sectional view of a structure after opening the second hard mask in accordance with an illustrative embodiment;

FIG. 15 is an illustration of a top view of a structure after opening the hard mask in accordance with an illustrative embodiment;

FIG. 16 is an illustration of a cross-sectional view of a structure during lithography in accordance with an illustrative embodiment;

FIG. 17 is an illustration of a top view of a structure during lithography in accordance with an illustrative embodiment;

FIG. 18 is an illustration of a cross-sectional view of a structure after performing a hard mask open in accordance with an illustrative embodiment;

FIG. 19 is an illustration of a top view of a structure after performing a hard mask open in accordance with an illustrative embodiment;

FIG. 20 is an illustration of a cross-sectional view of a structure after performing an interlayer dielectric reactive ion etch (ILDRIE) in accordance with an illustrative embodiment;

FIG. 21 is an illustration of a top view of a structure after performing an interlayer dielectric reactive ion etch (ILDRIE) in accordance with an illustrative embodiment;

FIG. 22 is an illustration of a cross-sectional view of a structure after performing a hard mask removal in accordance with an illustrative embodiment;

FIG. 23 is an illustration of a top view of a structure after performing a hard mask removal in accordance with an illustrative embodiment;

FIG. 24 is an illustration of a cross-sectional view of a structure after performing a metal deposition and CMP in accordance with an illustrative embodiment; and

FIG. 25 is an illustration of a top view of a structure after performing a metal deposition and CMP in accordance with an illustrative embodiment.

### DETAILED DESCRIPTION

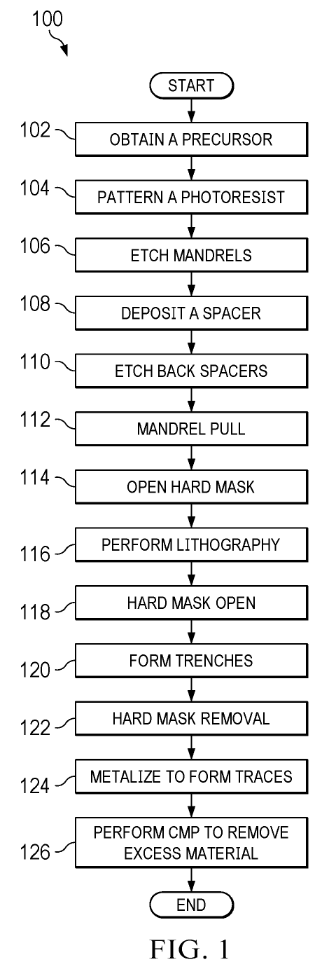

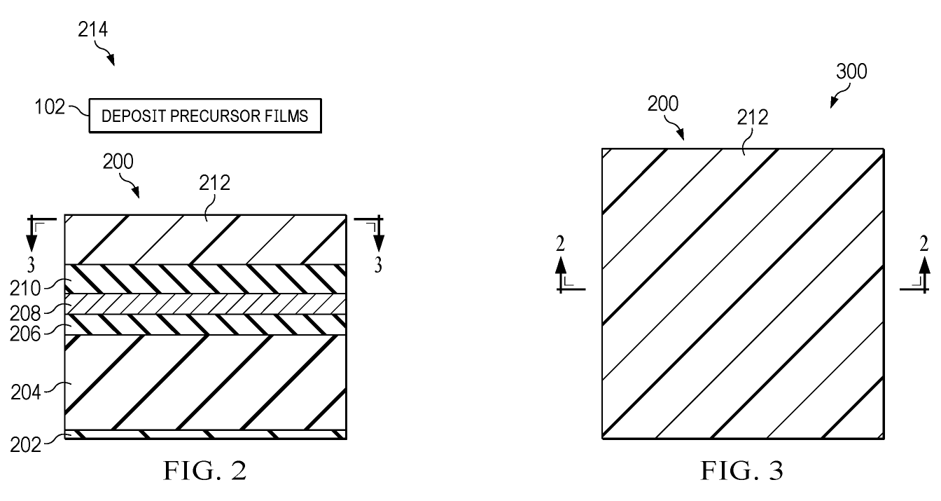

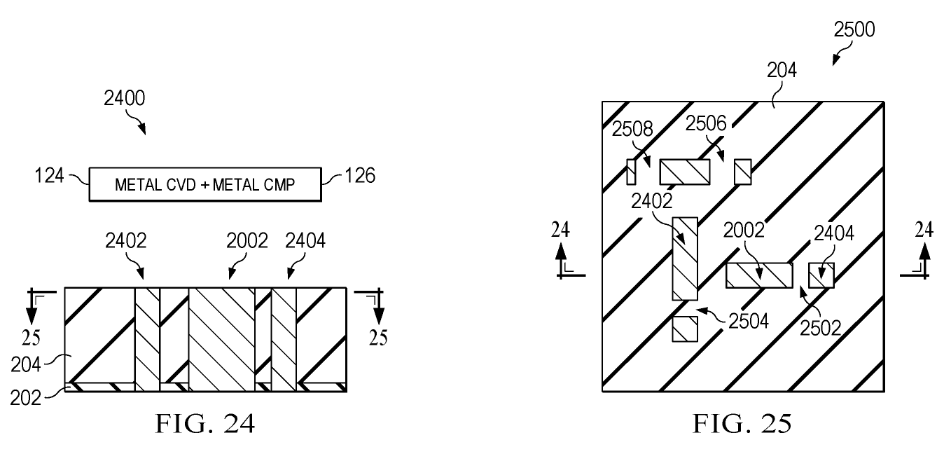

Turning now to FIG. 1, a flowchart illustrating steps of a self-aligned patterning process to form metal traces is depicted in accordance with an illustrative embodiment. FIG. 1 depicts, in a flowchart, steps of the self-aligned spacer cut process 100 to form metal traces 2402 shown in FIGS. 24 and 25, according to exemplary embodiments. FIGS. 2 through 23 depict, in schematics, structures to be produced by steps of the process that is shown in FIG. 1, according to exemplary embodiments. Even numbered figures are vertical cross-section views while odd numbered figures are top-down plan views that correspond to the preceding even numbered figures.

In step 102, a precursor is obtained. Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures.

After obtaining the precursor in step 102, a series of patterning processes is performed to form metal traces. In step 104 a photoresist is patterned using a photolithographic process.

As an exemplary subtractive process, in a photolithographic process, a layer of photoresist material may first be applied on top of a substrate, and then be exposed selectively according to a pre-determined device pattern or patterns. Portions of the photoresist that are exposed to light or other ionizing radiation (e.g., ultraviolet, electron beams, X-rays, etc.) may experience some changes in their solubility to certain solutions. The photoresist may then be developed in a developer solution, thereby removing the nonirradiated (in a negative resist) or irradiated (in a positive resist) portions of the resist layer, to create a photoresist pattern or photo-mask. The photoresist pattern or photo-mask may subsequently be copied or transferred to the substrate underneath the photoresist pattern.

After performing a photolithographic process, mandrels are etched in step 106. There are numerous techniques used by those skilled in the art to remove material at various stages of creating a semiconductor structure. As used herein, these processes are referred to generically as "etching". For example, etching includes techniques of wet etching, dry etching, chemical oxide removal (COR) etching, and reactive ion etching (ME), which are all known techniques to remove select material(s) when forming a semiconductor structure. The techniques and application of etching is well understood by those skilled in the art and, as such, a more detailed description of such processes is not presented herein.

Step 106 is performed to etch mandrels. Etching the mandrels removes hard mask material to generate the mandrels. In step 108, a spacer is deposited. In some illustrative examples, the spacer material can be deposited at 5-10nm thickness. After depositing the spacer material, in step 110, the spacer is etched back. In step 112, the mandrels are pulled. The mandrels are pulled by etching the hard mask material selective to the spacer. After pulling the mandrel, the patterned spacer material remains.

In step 114, opening the hard mask etches a pattern of the spacer into hard masks of the substrate to form a cutting pattern in the hard masks. In step 116, lithography is performed over the cutting pattern and substrate. In step 118, hard mask open forms the lithography pattern into the dielectric materials of the substrate. In step 120, the trenches are formed by etching the lithography pattern through the dielectric materials of the substrate. In some illustrative examples, step 120 can be an interlayer dielectric reactive ion etch (ILDRIE). In step 122, remaining hard mask is removed prior to metalizing to form traces in step 124. In step 126, CMP is performed to remove excess material.

The illustrative examples form small T2T spacer cuts in middle of line (MOL) applications. Process 100 generates metal traces with ends formed by hard masks blocking lithography and etching. Process 100 can generate metal traces with a small tip-to-tip (T2T) measurement such as 5-10nm. The illustrative examples can be used in other modules outside of MOL applications as well. The illustrative examples can be utilized in FIN, PC, and BEOL.

Process 100 utilizes a spacer to form smaller tip-to-tip measurements by blocking lithography and etch of portions of trenches. The spacer lines can have a thickness in the range of 5-10nm. The spacer pattern is etched into hard masks to form cutting patterns in the hard masks. Middle of Line (MOL) trench pattern lithography is performed over the hard masks with the cutting pattern. In steps 116, 118, and 120, by etching through the MOL pattern to dielectric films, the cutting pattern of the hard masks become gaps between ends of the metal traces.

Process 100 can generate metal traces without a pull back issue. Process 100 provides for metal trace generation that meets advanced technology design requirements.

Turning now to FIGS. 2 through 23, structures to be produced by steps of self-aligned spacer cut process 100 are depicted. In FIG. 2, an illustration of a cross-sectional view of a structure produced by depositing precursor films is depicted in accordance with an illustrative embodiment. In view 214, structure 200 is obtained from step 102 of depositing precursor films. Structure 200 comprises base layer 202, body layer 204, covering layer 206, first hard mask 208, second hard mask 210, and third hard mask 212. Each layer can comprise any desirable material and thickness of material based on creating a semiconductor structure.

In some illustrative examples, base layer 202 can take the form of silicon carbonitride (SiCN). In some illustrative examples, base layer 202 can take the form of silicon carbonitride (SiCN) 8 nm thick. In some illustrative examples, body layer 204 can take the form of silicon cyanate (SiCNO). In some illustrative examples, body layer 204 can take the form of silicon cyanate (SiCNO) 40 nm thick. In some illustrative examples, covering layer 206 comprises silicon oxynitride (SiON). In some illustrative examples, covering layer 206 comprises silicon oxynitride (SiON) 14 nm thick. In some illustrative examples, first hard mask 208 comprises titanium nitride (TiN). In some illustrative examples, first hard mask 208 comprises titanium nitride (TiN) 18 nm thick. In some illustrative examples, second hard mask 210 comprises silicon nitride (SiN). In some illustrative examples, second hard mask 210 comprises silicon nitride (SiN) 20 nm thick. In some illustrative examples, third hard mask 212 comprises amorphous silicon (aSi). In some illustrative examples, third hard mask 212 comprises amorphous silicon (aSi) 20 nm thick).

FIG. 3 is an illustration of a top view of a structure produced by depositing precursor films in accordance with an illustrative embodiment. View 300 is a top view of structure 200 from FIG. 2. In view 300, third hard mask 212 is visible.

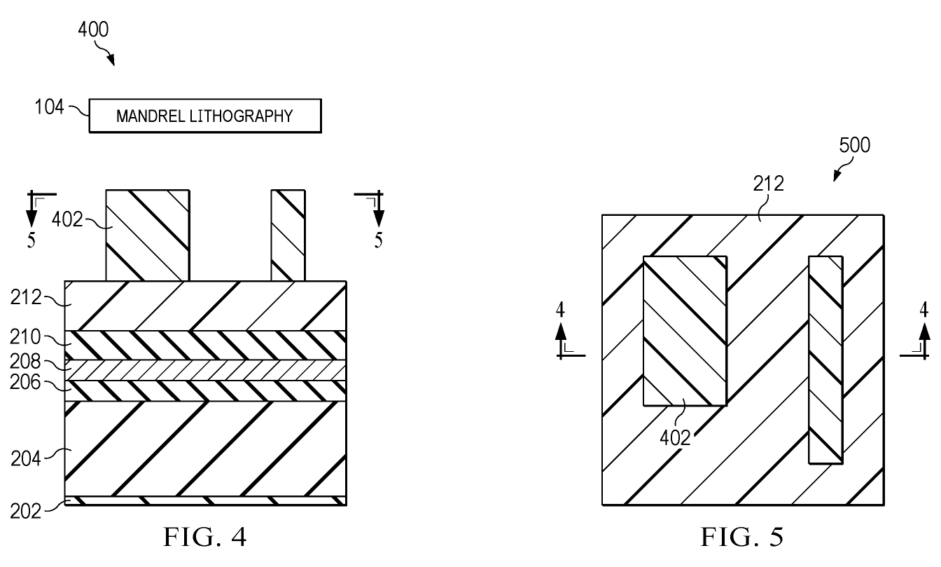

Turning now to FIG. 4, an illustration of a cross-sectional view of a structure during lithography is depicted in accordance with an illustrative embodiment. In step 104, mandrel lithography is depicted in view 400. In view 400, photoresist 402 is patterned. Although not depicted in FIG. 4, in some illustrative examples, a bottom anti-reflective coating can be present below photoresist 402.

FIG. 5 is an illustration of a top view of a structure during lithography in accordance with an illustrative embodiment. View 500 is a top view of photoresist 402 atop third hard mask 212. Photoresist 402 is designed to create mandrels from third hard mask 212.

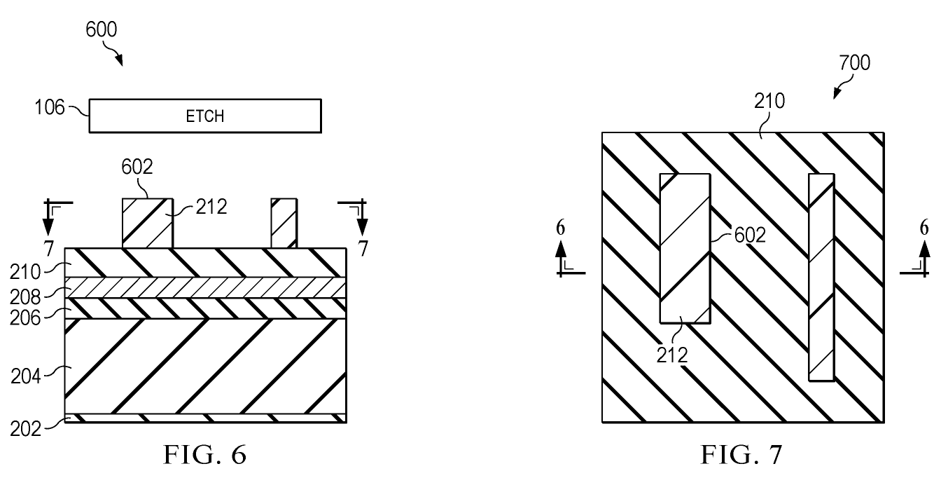

Turning now to FIG. 6, an illustration of a cross-sectional view of a structure after mandrel etch is depicted in accordance with an illustrative embodiment. In view 600 of step 106, etch mandrels is performed to generate mandrels 602 in third hard mask 212, based on photoresist 402 from mandrel lithography at step 104. Where material is removed around mandrels 602, second hard mask 210 is exposed.

FIG. 7 is an illustration of a top view of a structure after mandrel etch in accordance with an illustrative embodiment. View 700 is a top view of mandrels 602 formed of third hard mask 212 atop second hard mask 210.

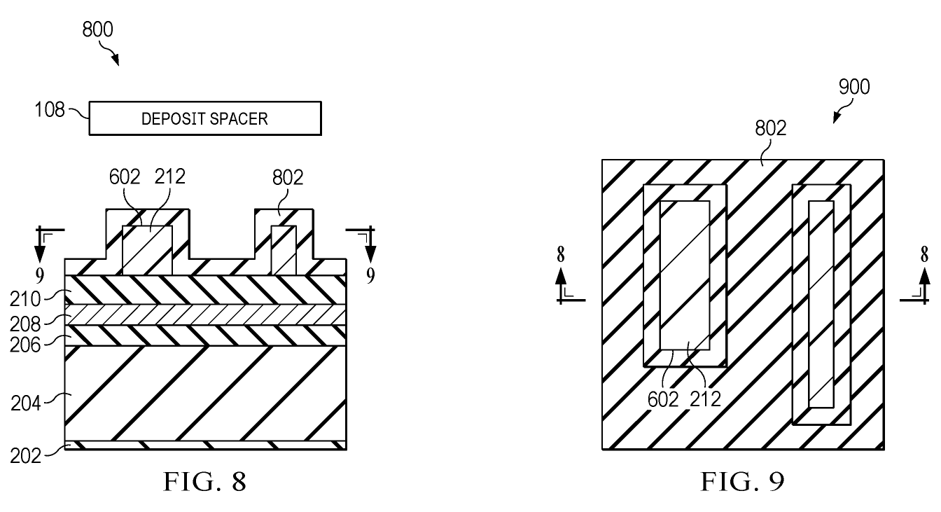

Turning now to FIG. 8, an illustration of a cross-sectional view of a structure after depositing a spacer material in accordance with an illustrative embodiment. In step 108, spacer 802 is deposited to cover third hard mask 212 and second hard mask 210. Spacer 802 is deposited so that it covers mandrels 602. Suitable materials for spacer 802 include, for example, one of TiN, TiOx, AlN, or AlOx.

FIG. 9 is an illustration of a top view of a structure after depositing a spacer material in accordance with an illustrative embodiment. View 900 is a view of spacer 802 over mandrels 602 and second hard mask 210.

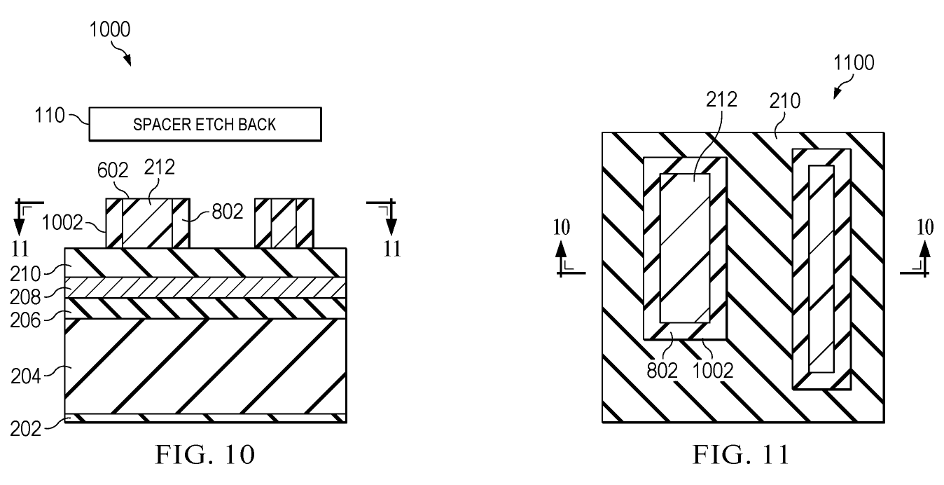

Turning now to FIG. 10, an illustration of a cross-sectional view of a structure after performing a spacer etch back is depicted in accordance with an illustrative embodiment. In step 110, spacer 802 is etched back. In view 1000, spacer 802 has been etched back to expose tops of mandrels 602. By etching back spacer 802, pattern 1002 is created. Pattern 1002 can include lines having a 5-10 nm width.

FIG. 11 is an illustration of a top view of a structure after performing a spacer etch back in accordance with an illustrative embodiment. Pattern 1002, mandrels 602, and second hard mask 210 is visible in view 1100.

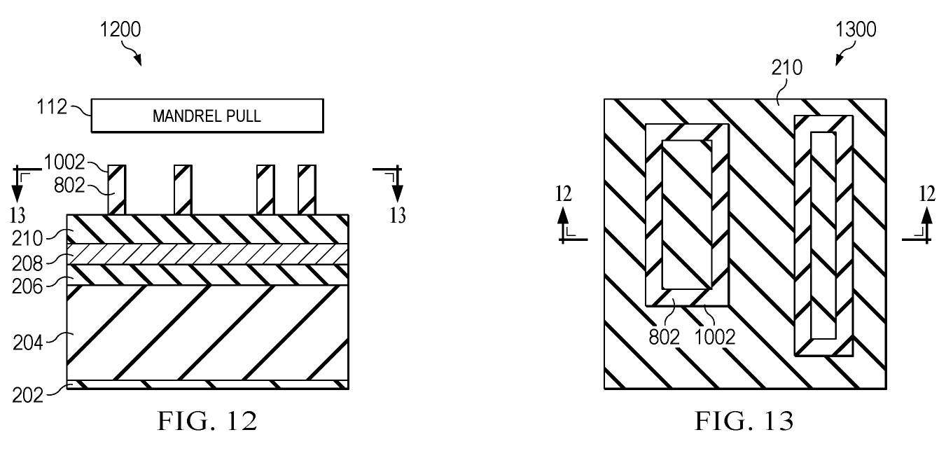

Turning now to FIG. 12, an illustration of a cross-sectional view of a structure after performing a mandrel pull is depicted in accordance with an illustrative embodiment. In step 112, mandrels 602 were “pulled” by etching third hard mask 212 selective to spacer 802. When third hard mask 212 comprises amorphous silicon (aSi), step 112 comprises etching amorphous silicon selective to spacer 802. Pulling the mandrels leaves pattern 1002 over second hard mask 210.

FIG. 13 is an illustration of a top view of a structure after performing a mandrel pull in accordance with an illustrative embodiment. In view 1300, pattern 1002 in spacer 802 is depicted over second hard mask 210. Not all portions of pattern 1002 are used for a self-align space cut process. Pattern 1002 maintains positioning of spacer 802 without falling over.

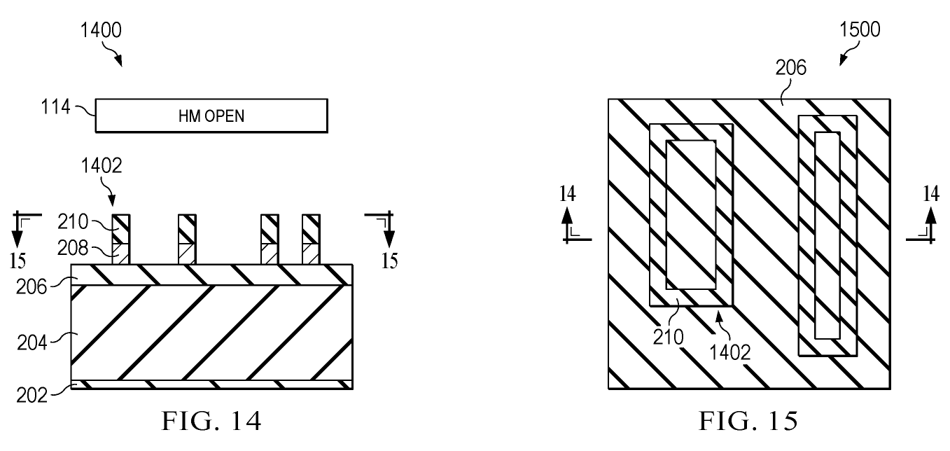

Turning now to FIG. 14, an illustration of a cross-sectional view of a structure after opening the second hard mask is depicted in accordance with an illustrative embodiment. In step 114, the hard mask open removes spacer 802. In step 114, the hard mask open also removes portions of second hard mask 210 and first hard mask 208 not covered by pattern 1002 in FIGS. 10 and 11. Cutting pattern 1402 is formed in second hard mask 210 and first hard mask 208 by the removal of second hard mask 210 and first hard mask 208 not covered by pattern 1002. Accordingly, pattern 1002 is transferred into second hard mask 210 and first hard mask 208 as cutting pattern 1402.

FIG. 15 is an illustration of a top view of a structure after opening the hard mask in accordance with an illustrative embodiment. In view 1500, cutting pattern 1402 formed in second hard mask 210 is depicted over covering layer 206. Not all portions of cutting pattern 1402 are used for a self-align space cut process. Cutting pattern 1402 has a shape configured to maintain positioning of second hard mask 210 without falling over.

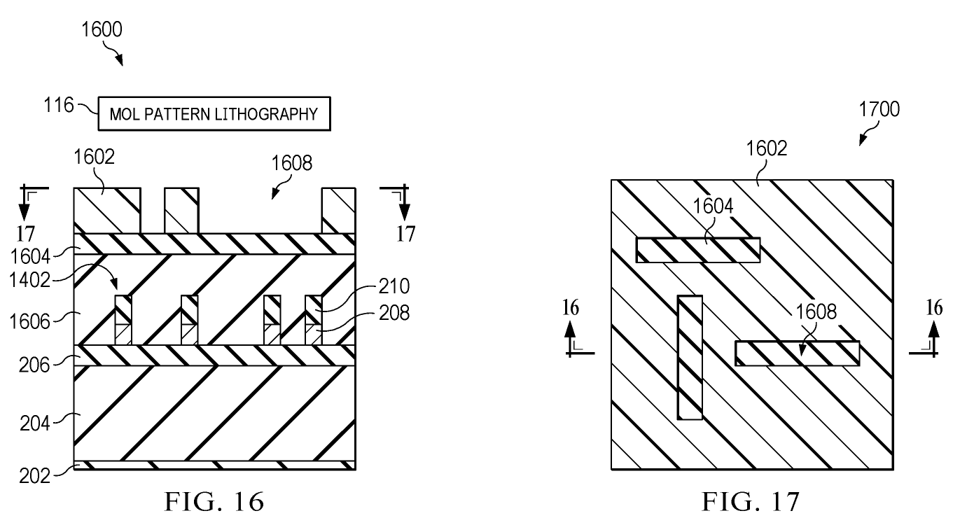

Turning now to FIG. 16, an illustration of a cross-sectional view of a structure during lithography is depicted in accordance with an illustrative embodiment. In step 116, pattern lithography is performed. The pattern lithography utilizes photoresist 1602 with openings 1608 corresponding to trenches to be formed in body layer 204 and base layer 202 for metal traces. Photolithography layers 1604 and 1606 are present to enable lithography over cutting pattern 1402.

FIG. 17 is an illustration of a top view of a structure during lithography in accordance with an illustrative embodiment. In view 1700, photoresist 1602 covers portions of covering layer 206 outside of metal traces to be formed in body layer 204 and base layer 202. Openings 1608 in photoresist 1602 will directly print positions for metal traces.

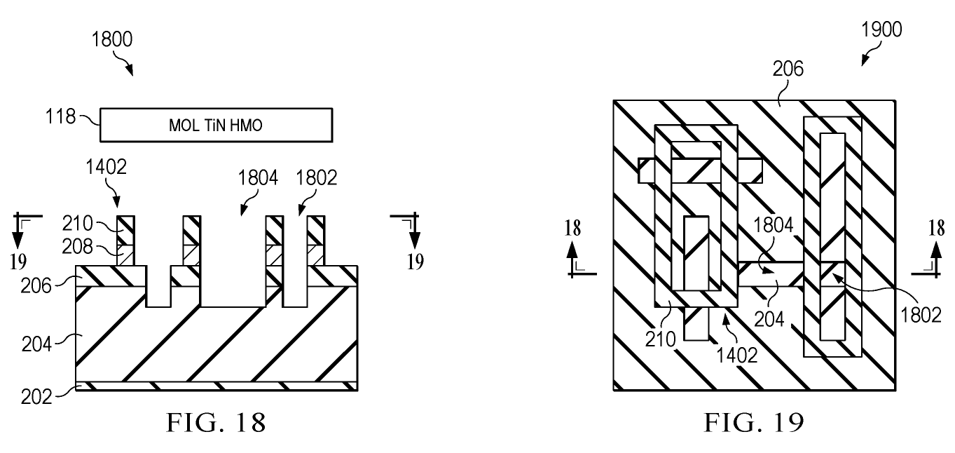

Turning now to FIG. 18, an illustration of a cross-sectional view of a structure after performing a hard mask open is depicted in accordance with an illustrative embodiment. In step 118 a middle of line (MOL) hard mask open (HMO) has been performed. The MOL HMO opens covering layer 206 and partially into body layer 204.

Pattern 1802 opened into covering layer 206 and into body layer 204 is a pattern for metal traces. Etches 1804 in body layer 204 will form a portion of trenches for metal traces.

FIG. 19 is an illustration of a top view of a structure after performing a hard mask open in accordance with an illustrative embodiment. In view 1900, cutting pattern 1402 is present over covering layer 206. Portions of body layer 204 are visible in pattern 1802.

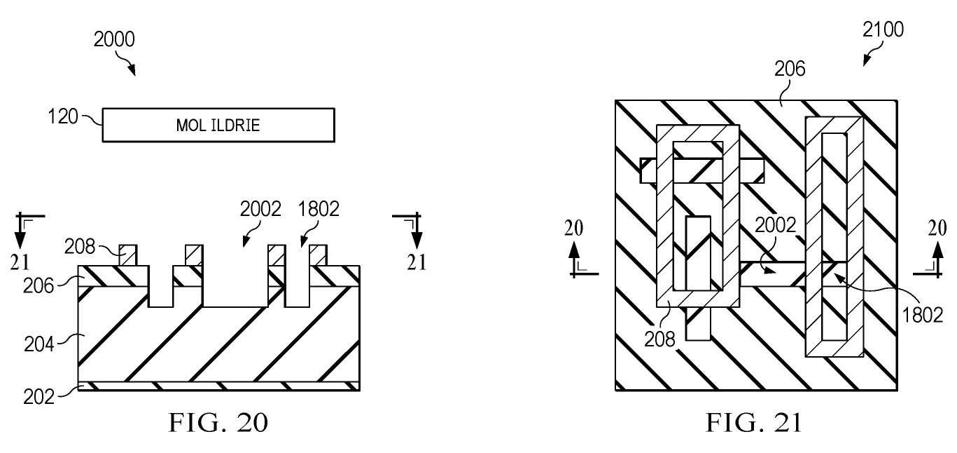

Turning now to FIG. 20 is an illustration of a cross-sectional view of a structure after performing an interlayer dielectric reactive ion etch (ILDRIE) is depicted in accordance with an illustrative embodiment. In step 120, the middle of line (MOL) interlayer dielectric reactive ion etch (ILDRIE) etches completely through body layer 204 and base layer 202.

FIG. 21 is an illustration of a top view of a structure after performing an interlayer dielectric reactive ion etch (ILDRIE) in accordance with an illustrative embodiment. In view 2100, cutting pattern 1402 of first hard mask 208 is present over covering layer 206 and trenches 2002 in pattern 1802.

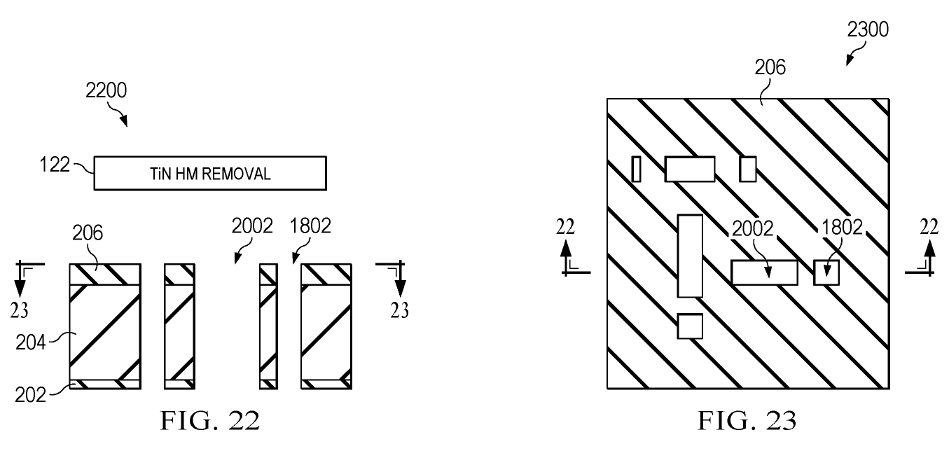

Turning now to FIG. 22, an illustration of a cross-sectional view of a structure after performing a hard mask removal is depicted in accordance with an illustrative embodiment. In step 122, first hard mask 208 has been removed in a hard mask removal step. Covering layer 206 remains over body layer 204 and base layer 202. Covering layer 206 has a same pattern, pattern 1802, cut into it as body layer 204 and base layer 202.

FIG. 23 is an illustration of a top view of a structure after performing a hard mask removal in accordance with an illustrative embodiment. In view 2300, pattern 1802 cut into covering layer 206 is visible.

Turning now to FIG. 24, an illustration of a cross-sectional view of a structure after performing a metal deposition and CMP is depicted in accordance with an illustrative embodiment. In step 124, metal 2402 is deposited. In step 126, metal chemical mechanical planarization (CMP) is performed to remove excess metal 2402 outside of trenches 2002. Metal 2402 can be any desirable metal. In some illustrative examples, metal 2402 is tungsten. Metal 2402 in trenches 2002 forms traces 2404. In some illustrative examples, metallizing trenches 2002 comprises filling the metal comprises vapor deposition of a metal selected from the list consisting of: copper, rhodium, ruthenium, tungsten, platinum, palladium, silver, or gold.

FIG. 25 is an illustration of a top view of a structure after performing a metal deposition and CMP in accordance with an illustrative embodiment. View 2500 is a top view of metal traces 2404 formed in a substrate, body layer 204 and base layer 202, by self-aligned spacer cut process, according to exemplary embodiments. Certain traces are broken by cuts, cut 2502, cut 2504, cut 2506, and cut 2508. Cut 2502, cut 2504, cut 2506, and cut 2508 can be referred to as T2T or tip to tip cuts. Cut 2502, cut 2504, cut 2506, and cut 2508 were generated by cutting pattern 1802 blocking portions of lithography in step 116. Traces 2404 do not have line pull back at cut 2502, cut 2504, cut 2506, and cut 2508. This is because traces 2404 are formed according to process 100, the steps of which are shown in FIG. 1. FIGS. 24 and 25 show the conclusion of the process 100, at step 124 and step 126 of metalizing to form traces and performing CMP to remove excess material.

In the illustrative examples, a method of forming metal traces is presented. A preliminary structure that comprises a substrate, a mandrel protruding from a substrate, and a spacer surrounding the mandrel is obtained. View 1000 is an example of a preliminary structure that comprises a substrate, a mandrel protruding from a substrate, and a spacer surrounding the mandrel. In this illustrative example, the substrate comprises base layer 202, body layer 204, covering layer 206, first hard mask 208, second hard mask 210.

The mandrel is pulled from the preliminary structure to leave the spacer on the substrate. View 1200 is an example of a view following a mandrel pull. In some illustrative examples, pulling the mandrel comprises etching the mandrel selective to the spacer. In some illustrative examples, pulling the mandrel comprises applying an etchant suitable for removing amorphous silicon.

A pattern of the spacer is etched into hard masks of the substrate to form a cutting pattern in the hard masks after pulling the mandrel. View 1400 is an example of a view following etching pattern 1002 of spacer 802 into hard masks, first hard mask 208 and second hard mask 210, to form cutting pattern 1402 into the hard masks. In some illustrative examples, etching the pattern of the spacer into the hard masks comprises applying an etchant suitable for removing silicon nitride and titanium nitride.

Trench lithography is performed over the cutting pattern and the substrate. View 1600 is an example of a view of performing trench lithography over cutting pattern 1402.

Etching through dielectrics of the substrate is performed to form trenches while the cutting pattern locally blocks etching to form tip-to-tip cuts between the trenches. View 2000 is an example of a view following an etch to form trenches while cutting pattern 1402 locally blocks etching. In some illustrative examples, etching through the dielectrics of the substrate to form trenches while the cutting pattern locally blocks etching to form tip-to-tip cuts comprises forming tip-to-tip cuts in the range of 5-10nm.

The trenches are metallized to form the metal traces. Chemical mechanical planarization is performed to remove excess metal. View 2400 is an example of a view following metallization and CMP. In some illustrative examples, metallizing the trenches to form metal traces comprises vapor deposition of a metal selected from the list consisting of: copper, rhodium, ruthenium, tungsten, platinum, palladium, silver, or gold.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of forming metal traces comprising:
obtaining a preliminary structure that comprises a substrate, a mandrel protruding from a substrate, and a spacer surrounding the mandrel;
pulling the mandrel from the preliminary structure to leave the spacer on the substrate;
etching a pattern of the spacer into hard masks of the substrate to form a cutting pattern in the hard masks after pulling the mandrel;
performing trench lithography over the cutting pattern and the substrate; and
etching through dielectrics of the substrate to form trenches while the cutting pattern locally blocks etching to form tip-to-tip cuts between the trenches.

2. The method of claim 1, wherein pulling the mandrel comprises etching the mandrel selective to the spacer.

3. The method of claim 1, wherein pulling the mandrel comprises applying an etchant suitable for removing amorphous silicon.

4. The method of claim 1, wherein etching the pattern of the spacer into the hard masks comprises applying an etchant suitable for removing silicon nitride and titanium nitride.

5. The method of claim 1, wherein etching through the dielectrics of the substrate to form trenches while the cutting pattern locally blocks etching to form tip-to-tip cuts comprises forming tip-to-tip cuts in the range of 5-10nm.

6. The method of claim 1, further comprising:
metallizing the trenches to form metal traces; and
performing chemical mechanical planarization to remove excess metal.

7. The method of claim 1, wherein metallizing the trenches to form metal traces comprises vapor deposition of a metal selected from the list consisting of: copper, rhodium, ruthenium, tungsten, platinum, palladium, silver, or gold.

8. A method of forming metal traces comprising:
obtaining a preliminary structure that comprises a substrate, a mandrel protruding from a substrate, and a spacer surrounding the mandrel;
pulling the mandrel to leave the spacer on the substrate;
etching a pattern of the spacer into hard masks of the substrate to form a cutting pattern in the hard masks;
performing lithography over the cutting pattern and the substrate;
etching through dielectrics of the substrate to form trenches such that the cutting pattern locally blocks etching to form tip-to-tip cuts in the range of 5-10nm between the trenches;
metallizing the trenches to form metal traces; and
performing chemical mechanical planarization to remove excess metal.

9. The method of claim 8, further comprising:
performing lithography over an outer hard mask of the substrate; and
etching the outer hard mask after lithography to form the mandrels.

10. The method of claim 8, wherein etching the pattern of the spacer into the hard masks comprises applying an etchant suitable for removing silicon nitride and titanium nitride.

11. A semiconductor structure comprising:
a substrate;
a cutting pattern formed of hard masks protruding from the substrate; and
photoresist positioned over the substrate such that openings in the photoresist direct print trenches to be formed in dielectrics of the substrate and the cutting pattern blocks portions of the openings to form tip-to-tip cuts in the trenches.

12. The semiconductor structure of claim 11, wherein the cutting pattern has a thickness in the range of 5-10nm.

13. The semiconductor structure of claim 11, wherein the substrate comprises a body layer of silicon cyanate.

14. The semiconductor structure of claim 13, wherein the body layer is about 40 nm thick.

15. The semiconductor structure of claim 11, wherein the substrate comprises a base layer of silicon carbonitride.

16. The semiconductor structure of claim 15, wherein the base layer is about 8 nm thick.

17. The semiconductor structure of claim 11, wherein the substrate comprises a covering layer of SiON.

18. The semiconductor structure of claim 17, wherein the covering layer is about 14 nm thick.

19. The semiconductor structure of claim 11, wherein the hard masks comprise silicon nitride and titanium nitride.

20. The semiconductor structure of claim 19, wherein the silicon nitride is about 20 nm thick, and wherein the titanium nitride is about 18 nm thick.
